(19) United States
(12) Patent Application Publication
(10) Pub. No.: US 2007/0247910 A1
(43) Pub. Date: Oct. 25, 2007

(54) NAND erase block size trimming apparatus and method

(75) Inventors: Hagop A. Nazarian, San Jose, CA (US); Frankie F. Roohparvar, Monte Sereno, CA (US)

Correspondence Address: LEFFERT JAY & POLGLAZE, P.A.;Attn: Daniel J. Polglaze, P. O. Box 581009, Minneapolis, MN, 55402, US

(73) Assignee: Micron Technology, Inc.

(21) Appl. No.: 11/407,856

(22) Filed: Apr. 20, 2006

(51) Int. Cl. G11C 16/04; G11C 11/34

(52) U.S. Cl. 365/185.17; 365/185.29; 365/185.11

(57) ABSTRACT

A NAND architecture includes a large NAND string sub-divided into smaller sub-strings for erasure, the string subdivided by a plurality of separator elements placed in series with the memory cells of the string, allowing for smaller erase blocks while maintaining the size of the string. The separator elements can be pass transistors or non-volatile or flash memory cells.

### FIELD

The present invention relates generally to memory devices and in particular the present invention relates to NAND memory devices.

### BACKGROUND

As block densities continue to increase in NAND memories, associated erase block sizes also increase. As erase block sizes increase, an increasing number of cells use a decreasing current supply. Further, drain side resistance increases with additional cells in a block.

Flash memories are typically NAND or NOR devices. In a NOR flash memory, a single cell is used to pull down an entire bitline in operation. In a NAND memory, there are typically 32 cells in a string in series. To access one cell, the other 31 cells are also used. As string sizes continue to increase, because resistance on the drain side increases, cell current decreases. There is a practical limit to the number of cells that can be placed in series given typical currents in a flash memory. In a NAND memory, all of the cells are in series, so they are ANDing together wordlines of the memory.

New architectures are contemplated that will continue to increase block sizes. Erase blocks typically are erased together in their entireties, so as block sizes increase, erase block sizes also increase.

However, larger strings can cause a number of problems. As cell current drops, the performance, already lowered in NAND devices because of large capacitors (on the order of 3-4 Pico Farads) and current of about 1 microampere out of each cell, and a time frame of on the order of microseconds to move a bitline up or down, also continues to drop. With 64 cells, current drops to about 0.5 microamperes. New memory architectures potentially can through charge sharing and the like reduce impact on performance of conductance of the cell, so that larger strings are feasible.

For the reasons stated above, and for other reasons stated below which will become apparent to those skilled in the art upon reading and understanding the present specification, there is a need in the art for maintaining efficient erase blocks with larger NAND strings.

### BRIEF DESCRIPTION OF DRAWINGS

FIG. 1 is a diagram of a NAND string according to one embodiment of the present invention;

FIG. 2 is a diagram of a NAND string according to another embodiment of the present invention;

FIG. 3 is a diagram of a NAND string according to yet another embodiment of the present invention;

FIG. 4 is a functional block diagram of an electrical system having at least one memory device with a NAND string according to one embodiment of the present invention; and

FIG. 5 is a functional block diagram of a memory module having at least one memory device in accordance with an embodiment of the invention.

### DETAILED DESCRIPTION

In the following detailed description of the invention, reference is made to the accompanying drawings that form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention.

The following detailed description is, therefore, not to be taken in a limiting sense, and the scope of the present invention is defined only by the appended claims, along with the full scope of equivalents to which such claims are entitled.

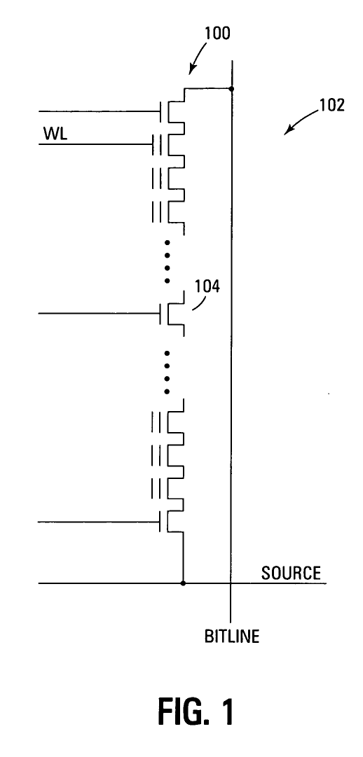

To combat the problem with longer and bigger NAND structure strings, the various embodiments of the present invention reduce the size of erase blocks in a NAND memory while maintaining the increased size of the actual strings of cells. In one embodiment 100 shown in FIG. 1, a NAND string 102 in a NAND memory has a plurality of non-volatile or flash cells in the string. The cells are connected in series and are connected to a bitline. In the NAND string 102, a divider element 104 is placed in series with the non-volatile cells in the string in order to subdivide the NAND string into multiple smaller sub-strings. These sub-strings are of a more traditional smaller size that is an acceptable size for a NAND erase block. As string size increases, more than one divider element 104 may be placed in series with the non-volatile cells at different locations, to break the larger NAND string into a plurality of smaller erase blocks.

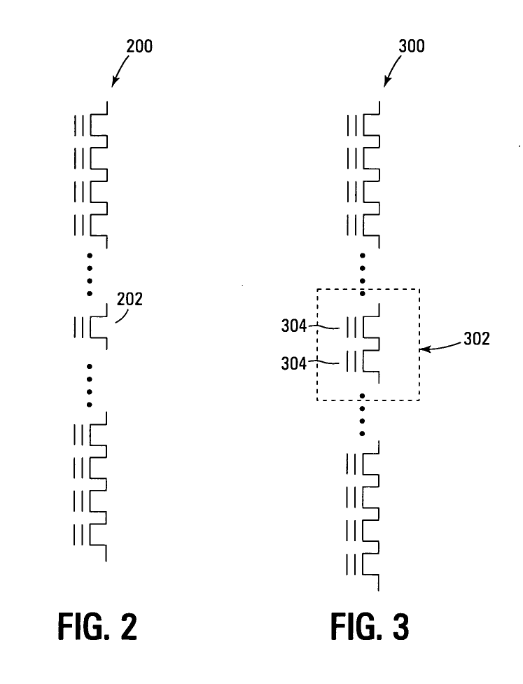

In the embodiment of FIG. 1, the divider element 104 is a transistor. In another embodiment 200, shown in FIG. 2, the divider element 202 is a flash cell. In yet another embodiment 300, shown in FIG. 3, the divider element 302 is a plurality of series connected flash cells 304. Such a configuration is shown in FIG. 3.

When a divider or separator element such as a series transistor, or one or a plurality of series connected non-volatile cells, is added between sub-strings of non-volatile memory cells, it essentially creates a NAND on top of NAND structure. By using 32 cells in series, each sub-string is a NAND structure. The resultant structure is a superNAND structure with a number of NAND structures that are NANDed to each other through the divider elements. This keeps the erase blocks small. What dictates the size of a NAND is not just the divider elements such as pass transistors or the like, but also the contacts that are required for the string as well. By having only pass transistors in the middle, the total number of gates is increased, but the erase block is kept smaller. Further, the impact of the various embodiments on memory real estate is smaller because there are not as many contacts required. The transistors in this embodiment share the diffusion. This reduces overall cell size overhead.

In certain modes of NAND programming, a bitline is forced to ground and a wordline is raised to 20 volts for programming. When a cell in the NAND string is selected to inhibit programming, the channel area of unselected NAND cells or strings are pre-charged to Vcc, and then isolated from any driving source. In other words, the cells or strings are floating but pre-charged to Vcc. When programming pulses are applied to the word line, the channel area of the floating strings are coupled up to high voltages, approximately 6-10 volts. The reduced differential voltage between the wordline voltage (approximately 20 volts) and the channel which is at 6-10 volts will prevent programming or inhibit tunneling, and hence inhibit programming of the cells. The differential voltage between the channel and the wordline is therefore approximately 12-15 volts, and that is not enough to program cells.

As NAND strings get larger, that is have more cells, each unselected wordline in the string is raised to a potential of 10 volts to couple the unselected cells (cells in the strings that are not to be programmed). As cell numbers in a NAND structure increase, a larger number of lines require 10 volts. The extra amount of voltage required for this results in more overhead in the form of more current and more power, and also leads to an increased amount of drain disturb in the system.

In one embodiment, a divider element is placed every 32 cells in a NAND string that is larger than 32 cells. This addition of a divider element, or in some embodiments multiple divider elements, adds to memory overhead slightly due to multiple erase block strings. However, peripheral circuitry for the memory is maintained at a smaller size, since the number of lines to be shifted for an erase procedure is kept at a reasonable size, in one embodiment 32. Die size is therefore maintained. For example, in a NAND structure with 128 cells, three divider elements are used to divide the 128 cell NAND string into four sub-strings of 32 cells each.

In the embodiments discussed above, a pass transistor, a non-volatile memory cell, flash cell, or a plurality of flash cells are used to separate large NAND strings into sub-strings of manageable erase block size. The transistor, non-volatile memory cell, flash cell, or plurality of flash cells, are a separator. Operation of the memory differs depending upon which separator element is used.

In operation, a superNAND structure of the various embodiments of the present invention functions as follows.

When the separator element is a pass transistor, to separate the larger NAND string into sub-strings, the pass transistor or pass transistors are turned off, isolating the particular sub-string to be erased, and an erase operation is performed on the sub-string.

When the separator element is a flash cell or a plurality of flash cells, at the beginning of an operation on the memory, in one embodiment, the separator cell or cells are programmed. In this embodiment, the cell or cells are programmed to a programmed state in which the cells are not on all the time. Alternatively, the separator cells are left in an erased state, and are then selected as high or low to separate the sub-strings.

In some embodiments, a single flash cell is used for each separator element. In other embodiments, using a single cell to isolate two strings from each other may not be sufficient to break the NAND string into sub-strings since bitlines are being coupled up to 8 or 9 volts, which may be sufficient to overcome the programming on a single flash cell, so two to three flash cells in series are used. Since the size of the cells is so small, two to three flash cells can be even smaller than using a peripheral transistor. As long as the cells are identified to the memory as separator cells, then they can be either programmed or erased, and by controlling the voltage on the gate of the separator cells, even if they are in an erased state, the cells can be maintained in an on or off state, or are programmed to a state where they can be turned on or off in a similar fashion as a transistor. Sub-strings are isolated and erased as sub-string erase blocks in an erase operation. Erase operations are known in the art, and will not be described in further detail herein. Breaking the strings into sub-strings with the separator elements allows for the maintenance of erase block size, while increasing the string size.

New schemes could have larger strings but smaller cell current without affecting performance. With other sensing schemes that are not impacted as much by having larger strings, this structure allows the movement to larger strings, which will impact overall die size in a positive way. Once schemes with increasing string size come about, this serial device could be applied to additional architectures that use larger strings.

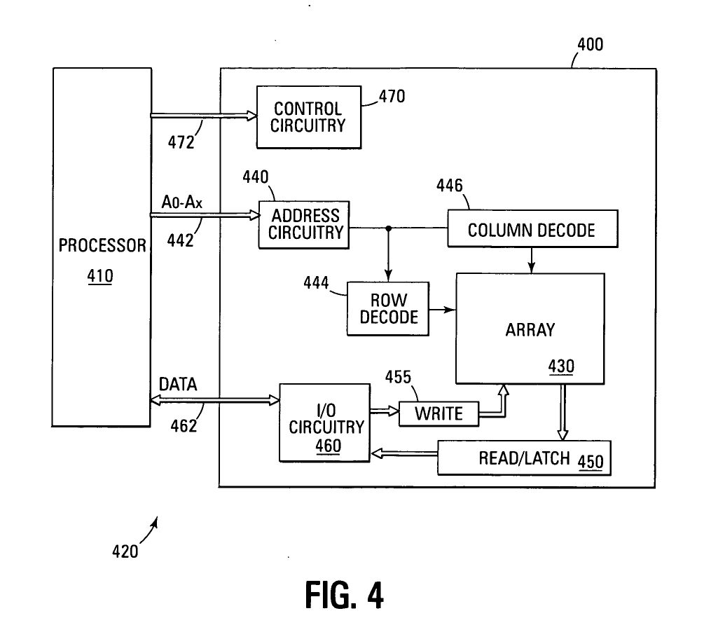

FIG. 4 is a functional block diagram of a memory device 400, such as a flash memory device, of one embodiment of the present invention, which is coupled to a processor 410. The memory device 400 and the processor 410 may form part of an electronic system 420. The memory device 400 has been simplified to focus on features of the memory that are helpful in understanding the present invention. The memory device includes an array of memory cells 430 having superNAND strings such as strings 100, 200, or 300 described above. The memory array 430 is arranged in banks of rows and columns.

An address buffer circuit 440 is provided to latch address signals provided on address input connections A0-Ax 442. Address signals are received and decoded by row decoder 444 and a column decoder 446 to access the memory array 430. It will be appreciated by those skilled in the art, with the benefit of the present description, that the number of address input connections depends upon the density and architecture of the memory array. That is, the number of addresses increases with both increased memory cell counts and increased bank and block counts.

The memory device reads data in the array 430 by sensing voltage or current changes in the memory array columns using sense/latch circuitry 450. The sense/latch circuitry, in one embodiment, is coupled to read and latch a row of data from the memory array. Data input and output buffer circuitry 460 is included for bi-directional data communication over a plurality of data (DQ) connections 462 with the processor 410, and is connected to write circuitry 455 and read/latch circuitry 450 for performing read and write operations on the memory 400.

Command control circuit 470 decodes signals provided on control connections 472 from the processor 410. These signals are used to control the operations on the memory array 430, including data read, data write, and erase operations. The flash memory device has been simplified to facilitate a basic understanding of the features of the memory. A more detailed understanding of internal circuitry and functions of flash memories are known to those skilled in the art.

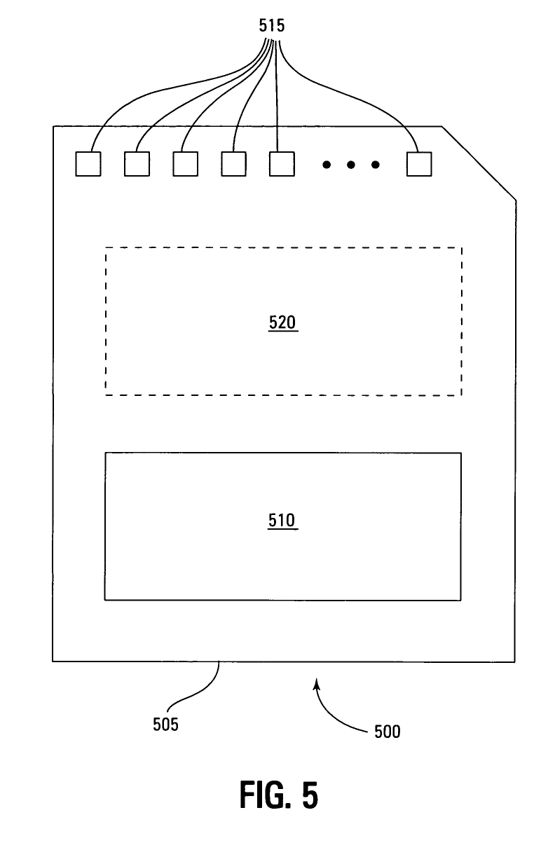

FIG. 5 is an illustration of an exemplary memory module 500. Memory module 500 is illustrated as a memory card, although the concepts discussed with reference to memory module 500 are applicable to other types of removable or portable memory, e.g., USB flash drives, and are intended to be within the scope of “memory module” as used herein. In addition, although one example form factor is depicted in FIG. 5, these concepts are applicable to other form factors as well.

In some embodiments, memory module 500 will include a housing 505 (as depicted) to enclose one or more memory devices 510, though such a housing is not essential to all devices or device applications. At least one memory device 510 is a non-volatile memory including a superNAND string according to various embodiments of the present invention. Where present, the housing 505 includes one or more contacts 515 for communication with a host device. Examples of host devices include digital cameras, digital recording and playback devices, PDAs, personal computers, memory card readers, interface hubs and the like. For some embodiments, the contacts 515 are in the form of a standardized interface. For example, with a USB flash drive, the contacts 515 might be in the form of a USB Type-A male connector. For some embodiments, the contacts 515 are in the form of a semi-proprietary interface, such as might be found on CompactFlash™ memory cards licensed by SanDisk Corporation, Memory Stick™ memory cards licensed by Sony Corporation, SD Secure Digital™ memory cards licensed by Toshiba Corporation and the like. In general, however, contacts 515 provide an interface for passing control, address and/or data signals between the memory module 500 and a host having compatible receptors for the contacts 515.

The memory module 500 may optionally include additional circuitry 520 which may be one or more integrated circuits and/or discrete components. For some embodiments, the additional circuitry 520 may include a memory controller for controlling access across multiple memory devices 510 and/or for providing a translation layer between an external host and a memory device 510. For example, there may not be a one-to-one correspondence between the number of contacts 515 and a number of I/O connections to the one or more memory devices 510. Thus, a memory controller could selectively couple an I/O connection (not shown in Figure X) of a memory device 510 to receive the appropriate signal at the appropriate I/O connection at the appropriate time or to provide the appropriate signal at the appropriate contact 515 at the appropriate time. Similarly, the communication protocol between a host and the memory module 500 may be different than what is required for access of a memory device 510. A memory controller could then translate the command sequences received from a host into the appropriate command sequences to achieve the desired access to the memory device 510. Such translation may further include changes in signal voltage levels in addition to command sequences.

The additional circuitry 520 may further include functionality unrelated to control of a memory device 510 such as logic functions as might be performed by an ASIC (application specific integrated circuit). Also, the additional circuitry 520 may include circuitry to restrict read or write access to the memory module 500, such as password protection, biometrics or the like. The additional circuitry 520 may include circuitry to indicate a status of the memory module 500. For example, the additional circuitry 520 may include functionality to determine whether power is being supplied to the memory module 500 and whether the memory module 500 is currently being accessed, and to display an indication of its status, such as a solid light while powered and a flashing light while being accessed. The additional circuitry 520 may further include passive devices, such as decoupling capacitors to help regulate power requirements within the memory module 500.

### CONCLUSION

A NAND erase block size trimming circuit and method have been described that include placing a divider element in series with non-volatile memory cells within a large NAND string to break the NAND string into a plurality of sub-strings for manageable erase block sizes, without making the NAND string smaller, and without increasing die size and cell size overhead.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

What is claimed is:

1. A NAND memory string, comprising:
a string of series connected non-volatile memory cells; and
at least one separator element in series with the non-volatile cells to separate the string into a plurality of sub-strings, to reduce an erase block size.

2. The NAND of claim 1, wherein the separator element is a pass transistor.

3. The NAND of claim 1, wherein the separator element is a non-volatile memory cell.

4. The NAND of claim 1, wherein the separator element is a plurality of non-volatile memory cells connected in series with each other.

5. The NAND of claim 1, wherein the plurality of non-volatile memory cells comprises two non-volatile memory cells in series.

6. The NAND of claim 1, wherein the separator element is a flash memory cell.

7. A memory device, comprising:
an array of non-volatile memory cells having series-coupled strings of non-volatile memory cells; and
circuitry for control and/or access of the array of non-volatile memory cells;
wherein the series-coupled strings of non-volatile memory cells each comprises:
a NAND string having a plurality of non-volatile memory cells, and
at least one separator element in series with the non-volatile cells to separate the string into a plurality of sub-strings, to reduce an erase block size.

8. The memory device of claim 7, wherein the separator element is a pass transistor.

9. The memory device of claim 7, wherein the separator element is a non-volatile memory cell.

10. The memory device of claim 7, wherein the separator element is a plurality of non-volatile memory cells connected in series with each other.

11. The memory device of claim 7, wherein the plurality of non-volatile memory cells comprises two non-volatile memory cells in series.

12. The memory device of claim 7, wherein the separator element is a flash memory cell.

13. A flash memory device, comprising:
an array of flash memory cells having series-coupled strings of flash memory cells; and
circuitry for control and/or access of the array of flash memory cells;
wherein the series-coupled strings of flash memory cells each comprises:
a NAND string having a plurality of flash memory cells, and
at least one separator element in series with the flash cells to separate the string into a plurality of sub-strings, to reduce an erase block size.

14. A memory module, comprising:
a plurality of contacts; and
two or more memory devices, each having access lines selectively coupled to the plurality of contacts;
wherein at least one of the memory devices comprises:
an array of non-volatile memory cells having series-coupled strings of non-volatile memory cells; and
circuitry for control and/or access of the array of non-volatile memory cells;
wherein the series-coupled strings of non-volatile memory cells each comprises:
a NAND string having a plurality of non-volatile memory cells, and
at least one separator element in series with the non-volatile cells to separate the string into a plurality of sub-strings, to reduce an erase block size.

15. The memory module of claim 14, wherein the separator element is a pass transistor.

16. The memory module of claim 14, wherein the separator element is a non-volatile memory cell.

17. The memory module of claim 14, wherein the separator element is a plurality of non-volatile memory cells connected in series with each other.

18. The memory module of claim 14, wherein the plurality of non-volatile memory cells comprises two non-volatile memory cells in series.

19. The memory module of claim 14, wherein the separator element is a flash memory cell.

20. A memory module, comprising:
a housing having a plurality of contacts; and
one or more memory devices enclosed in the housing and selectively coupled to the plurality of contacts;
wherein at least one of the memory devices comprises:
an array of non-volatile memory cells having series-coupled strings of non-volatile memory cells; and
circuitry for control and/or access of the array of non-volatile memory cells;
wherein the series-coupled strings of non-volatile memory cells each comprises:
a NAND string having a plurality of non-volatile memory cells, and
at least one separator element in series with the non-volatile cells to separate the string into a plurality of sub-strings, to reduce an erase block size.

21. The memory module of claim 20, wherein the separator element is a pass transistor.

22. The memory module of claim 20, wherein the separator element is a non-volatile memory cell.

23. The memory module of claim 20, wherein the separator element is a plurality of non-volatile memory cells connected in series with each other.

24. The memory module of claim 20, wherein the plurality of non-volatile memory cells comprises two non-volatile memory cells in series.

25. The memory module of claim 20, wherein the separator element is a flash memory cell.

26. An electronic system, comprising:
a processor; and
one or more memory device coupled to the processor, wherein at least one of the memory devices comprises:
an array of non-volatile memory cells having series-coupled strings of non-volatile memory cells; and
circuitry for control and/or access of the array of non-volatile memory cells;
wherein the series-coupled strings of non-volatile memory cells each comprises:
a NAND string having a plurality of non-volatile memory cells, and
at least one separator element in series with the non-volatile cells to separate the string into a plurality of sub-strings, to reduce an erase block size.

27. The electronic system of claim 26, wherein the separator element is a pass transistor.

28. The electronic system of claim 26, wherein the separator element is a non-volatile memory cell.

29. The electronic system of claim 26, wherein the separator element is a plurality of non-volatile memory cells connected in series with each other.

30. The electronic system of claim 26, wherein the plurality of non-volatile memory cells comprises two non-volatile memory cells in series.

31. The electronic system of claim 26, wherein the separator element is a flash memory cell.

32. A method of trimming erase block size in a NAND string, comprising:
placing a separator element in series with the string, the separator element creating two sub-strings of NAND cells separated by the separator element; and
isolating a subsection of the NAND string for erasure.

33. The method of claim 32, wherein the separator element is a pass transistor, and wherein isolating comprises turning the pass transistor off.

34. The method of claim 32, wherein the separator element is a non-volatile memory cell, and wherein isolating comprises:
programming the separator element; and
controlling the voltage on the gate of the separator element to turn the separator element off for an erase operation.

35. The method of claim 32, wherein the separator element is a plurality of non-volatile memory cells connected in series with each other, and wherein isolating comprises:
programming each separator element; and
controlling the voltage on the gate of each separator element to turn at least one separator element off for an erase operation.

36. The method of claim 35, wherein the separator element comprises two non-volatile memory cells connected in series with each other, and wherein isolating comprises:
programming each separator element; and
controlling the voltage on the gate of each separator element to turn at least one separator element off for an erase operation.

37. The method of claim 32, wherein the separator element is a flash memory cell.

38. The method of claim 32, wherein the separator element is a non-volatile memory cell, and wherein isolating comprises:
erasing the separator element; and
controlling the voltage on the gate of the separator element to turn the separator element off for an erase operation.

39. The method of claim 32, wherein the separator element is a plurality of non-volatile memory cells connected in series with each other, and wherein isolating comprises:
erasing each separator element; and
controlling the voltage on the gate of each separator element to turn at least one separator element off for an erase operation.

40. The method of claim 32, wherein the separator element comprises two non-volatile memory cells connected in series with each other, and wherein isolating comprises:
erasing each separator element; and
controlling the voltage on the gate of each separator element to turn at least one separator element off for an erase operation.

41. A method of operating a NAND memory, comprising:
isolating a portion of a NAND string for erase procedures; and
erasing the isolated portion of the NAND string.

42. The method of claim 41, wherein isolating comprises turning off at least one of a plurality of separator elements, the separator elements subdividing a string of the NAND memory into sub-strings.

43. The method of claim 42, wherein each separator element is a pass transistor, and wherein isolating comprises turning the pass transistor off.

44. The method of claim 42, wherein each separator element is a non-volatile memory cell, and wherein isolating comprises:
programming the separator element; and
controlling the voltage on the gate of the separator element to turn the separator element off for an erase operation.

45. The method of claim 42, wherein each separator element is a plurality of non-volatile memory cells connected in series with each other, and wherein isolating comprises:
programming each separator element; and
controlling the voltage on the gate of each separator element to turn at least one separator element off for an erase operation.

46. The method of claim 42, wherein each separator element comprises two non-volatile memory cells connected in series with each other, and wherein isolating comprises:
programming each separator element; and
controlling the voltage on the gate of each separator element to turn at least one separator element off for an erase operation.

47. The method of claim 42, wherein each separator element is a flash memory cell.

48. The method of claim 42, wherein each separator element is a non-volatile memory cell, and wherein isolating comprises:
erasing the separator element; and
controlling the voltage on the gate of the separator element to turn the separator element off for an erase operation.

49. The method of claim 42, wherein each separator element is a plurality of non-volatile memory cells connected in series with each other, and wherein isolating comprises:
erasing each separator element; and
controlling the voltage on the gate of each separator element to turn at least one separator element off for an erase operation.

50. The method of claim 42, wherein each separator element comprises two non-volatile memory cells connected in series with each other, and wherein isolating comprises:
erasing each separator element; and
controlling the voltage on the gate of each separator element to turn at least one separator element off for an erase operation.

51. A method of trimming erase block size in a NAND string, comprising:
placing a pass transistor in series with the string, the pass transistor creating two sub-strings of NAND cells separated by the pass transistor; and
turning off the pass transistor to isolate a subsection of the NAND string for erasure.

52. The method of claim 51, and further comprising a plurality of pass transistors, in series with the string at selected positions to divide the string into a plurality of sub-strings.

53. A method of trimming erase block size in a NAND string, comprising:
placing at least one separator element in series with the NAND string; and
programming the at least one separator element to isolate a subsection of the NAND string for erasure.

54. The method of claim 53, and further comprising a plurality of separator elements, in series with the string, the plurality of flash cell separators dividing the string into a plurality of sub-strings.

55. A method of trimming NAND memory device erase block size, comprising:
positioning a plurality of separator elements in a NAND string, each separator element operable to isolate a section of the NAND string for an erase operation of the device.
